(19) United States
(12) Patent Application Publication
(10) Pub. No.: US 2003/0064325 A1
(43) Pub. Date: Apr. 3, 2003

(54) Method of manufacturing printed circuit board having wiring layers electrically connected via solid cylindrical copper interconnecting bodies

(75) Inventors: Cheng-Hsien Chou, Tu-Cheng City (TW); Chien-Jung Huang, Tu-Cheng City (TW); Lin-Chuan Lee, Tu-Cheng City (TW)

Correspondence Address: DOUGHERTY & TROXELL, ATTORNEYS AT LAW, Suite 1404, 5205 Leesburg Pike, Falls Church, VA, 22041, US

(73) Assignee: Unitech Printed Circuit Board Corp.

(21) Appl. No.: 09/969,043

(22) Filed: Oct. 3, 2001

(51) Int. Cl. G03F 7/00

(52) U.S. Cl. 430/314; 430/311; 430/318

(57) ABSTRACT

A method of manufacturing a printed circuit board (PCB) having wiring layers electrically connected via solid cylindrical copper interconnecting bodies includes the following steps: locally providing on a base or an insulated layer with a first copper foil wiring layer; fully coating the first wiring layer with a conductive layer; coating areas on the first wiring layer that are not used for interconnection purpose with a layer of dry-film resist to expose other areas on the first wiring layer to be used for interconnection purpose; removing the conductive layer by micro etching; forming solid cylindrical copper interconnecting bodies of a desired height on the interconnecting areas through electric plating; removing the dry-film resist, so that the solid cylindrical copper interconnecting bodies consisting of pure copper project from the interconnecting areas; and providing a second wiring layer over the first wiring layer.

### BACKGROUND OF THE INVENTION

The present invention relates to a method of manufacturing printed circuit board (PCB) having wiring layers electrically connected via solid cylindrical copper interconnecting bodies, and more particularly to a method of manufacturing a PCB having two or more wiring layers electrically connected via solid cylindrical copper interconnecting bodies consisting of pure copper, so that problems existing in the conventional methods, such as reduced cylindrical copper body diameter during etching process, could be avoided to effectively upgrade the electric connection quality of the circuit board.

Most of the currently commercially available electronic products are extremely compact in dimensions. Electronic parts for these products and printed circuit boards (PCB) on which the electronic parts are mounted are therefore relatively miniaturized and lightweight. That is, there is an increasing demand for a PCB having highly densely arranged electronic components. One of the ways to obtain a PCB having highly densely arranged electronic components is to increase the density of wiring on the wiring layer of the PCB. Or, two or more wiring layers could be laminated on the PCB to provide a multilayered PCB.

The multilayered printed circuit boards may be generally divided according to their manufacturing manners into two types, namely, compression type and lamination type. In the compression-type multilayered PCB, multiple bases are respectively formed with wiring layers. Then, a thin layer of insulating material, such as a film formed from fiberglass-added resin, is provided between every two adjacent bases to serve as an intermediate layer. Thereafter, the multiple bases are bonded together through thermocompression and form a multilayered PCB. In the lamination-type multilayered PCB, each base provided with a wiring layer is coated with an insulating layer over the wiring layer, and another wiring layer is then provided on the insulating layer. The wiring layer and the insulating layer are alternately laminated on the base to form a multilayered PCB.

In the wiring design for a multilayered PCB, it is necessary to build interconnections at some particular areas of the wiring layers to electrically connect these wiring layers. Currently, there are many different ways to achieve this purpose. For example, laser or mechanical drilling unit is employed in the process of manufacturing the multilayered PCB to form intermediate holes at desired interconnecting areas, and an electrically conductive layer is then formed in each intermediate hole through electric plating. Or, in the process of manufacturing the lamination-type multilayered PCB, solid cylindrical copper interconnecting bodies are produced on a wiring layer at intended interconnecting areas for directly contacting with contacts at another wiring layer. Since the cylindrical copper interconnection may be more effectively controlled in terms of the quality of the formed cylindrical copper and provides higher electrical connection efficiency, as compared with the plated intermediate holes, it has become a common way of interconnection to electrically connect two or more wiring layers on the multilayered PCB.

There are many inventions involving the forming of cylindrical copper interconnecting bodies on the multilayered PCB, such as Japanese Patent Application No. 05-127902 (Tokukaihei 6-314878 published on Nov. 8, 1994) entitled “Manufacture of Printed Wiring Board”, Taiwan Patent Application No. 88101991 (published under Publication No. 407447) entitled “Printed Circuit Board with Solid-state Interconnecting bodies and Method for Manufacturing the Same”, and Taiwan Patent Application No. 87120091 (published under Publication No. 411748) entitled “Method of Manufacturing Multilayered Wiring Base”. However, all the solid cylindrical copper bodies for interconnection obtained from the above-mentioned inventions include at least a layer of metal that is not pure copper. For example, Taiwan Patent Application No. 88101991 (published under Publication No. 407447) entitled “Printed Circuit Board with Solid-state Interconnecting bodies and Method for Manufacturing the Same” discloses solid cylindrical copper interconnecting bodies having an etching resist layer that is a tin-lead metal; and both Japanese Patent Application No. 05-127902 (Tokukaihei 6-314878 published on Nov. 8, 1994) entitled “Manufacture of Printed Wiring Board” and Taiwan Patent Application No. 87120091 (published under Publication No. 411748) entitled “Method of Manufacturing Multilayered Wiring Base” disclose solid cylindrical copper interconnecting bodies having an electrically conductive layer that is not pure copper (such as a Ni—Au alloy). Moreover, in Taiwan Patent Application No. 87120091 (published under Publication No. 411748), the desired solid cylindrical copper interconnecting bodies are obtained by directly etching an entire metal body having a uniform thickness, that is, an electrically plated copper layer having a thickness the same as that for the desired solid cylindrical copper interconnecting bodies. Such etching process continues over a prolonged time and would even result in unevenly reduced diameters of the finally formed cylindrical copper bodies due to etching. The solid cylindrical copper interconnecting bodies having different diameters have inconsistent resistance values and directly adversely affect the quality of electric connection that may be provided by these cylindrical copper interconnecting bodies. The PCB having cylindrical copper interconnecting bodies without uniform diameter would also has poor quality.

### SUMMARY OF THE INVENTION

It is therefore a primary object of the present invention to provide a method of manufacturing printed circuit board (PCB) having wiring layers electrically connected via solid cylindrical copper interconnecting bodies, wherein all the solid cylindrical copper interconnecting bodies formed on the PCB are pure copper and have a uniform diameter that would not be reduced in the process of etching the wiring layers. Therefore, the PCB manufactured in the method of the present invention provides effectively upgraded electric connection quality.

To achieve the above and other objects, the method of the present invention for manufacturing a printed circuit board having wiring layers electrically connected via solid cylindrical copper interconnecting bodies includes the following steps for forming the solid cylindrical copper interconnecting bodies:

(1) Coating a first copper foil wiring layer on a base or an insulated layer with an electrically conductive layer. The electrically conductive layer may be formed with skills known in the art, such as using non-electrolytic copper or forming an electric plating layer;

(2) Coating areas on the first wiring layer that are not used for interconnection purpose with a layer of dry-film resist to protect these areas against subsequent electric plating process, such that other areas on the first wiring layer that are to be used for interconnection purpose are exposed to outside;

(3) Removing he electrically conductive layer on the interconnecting areas by way of micro etching;

(4) Forming solid cylindrical copper interconnecting bodies on the interconnecting areas by way of electric plating. The electric plating continues until the cylindrical copper interconnecting bodies reach a desired height;

(5) Removing the dry-film resist, so that the solid cylindrical copper interconnecting bodies consisting of pure copper project from the interconnecting areas; and

(6) Forming a second wiring layer over the first wiring layer on the PCB using the laminating method known in the art.

### BRIEF DESCRIPTION OF THE DRAWINGS

The structure and the technical means adopted by the present invention to achieve the above and other objects can be best understood by referring to the following detailed description of the preferred embodiments and the accompanying drawing, wherein

FIG. 1 illustrates steps included in the method of the present invention for forming solid cylindrical copper interconnecting bodies for electrically connecting wiring layers on a printed circuit board.

### DETAILED DESCRIPTION OF THE PREFERRED EMBODIMENTS

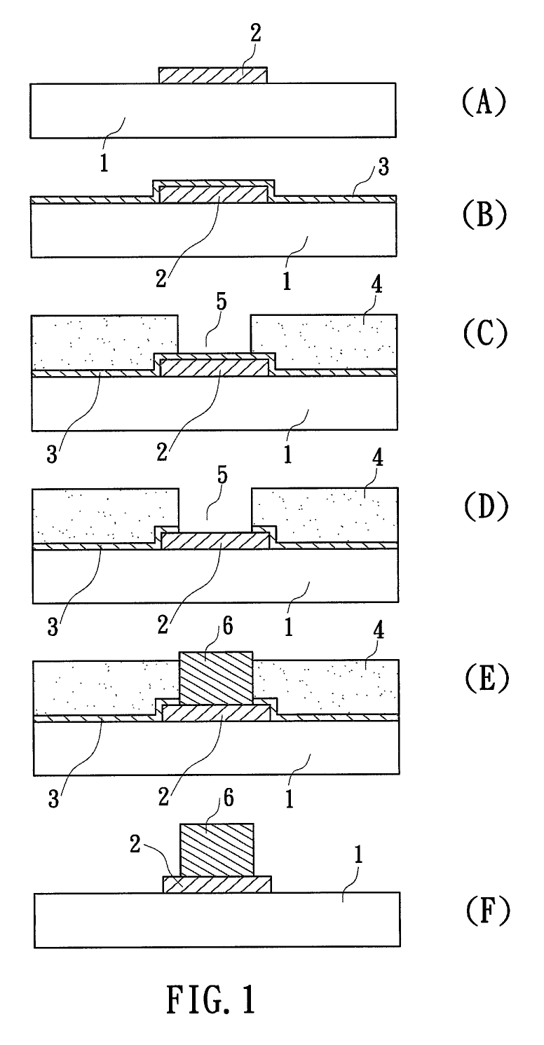

Please refer to FIG. 1 that illustrates steps (A) to (F) for forming solid cylindrical copper interconnecting bodies for electrically connecting wiring layers on a printed circuit board.

In step (A), a base 1 or an insulated layer is locally provided at one side with a layer of copper foil to serve as a first wiring layer 2. This step may be done in a manner known in the art. In step (B), the side of the base 1 having the first wiring layer 2 is fully coated with an electrically conductive layer 3. In step (C), areas on the first wiring layer 2 that are not used for interconnection purpose are coated with a layer of dry-film resist 4 to protect these areas against subsequent electric plating process, such that other areas on the first wiring layer 2 that are to be used for interconnecting purpose are exposed to outside and form interconnecting areas 5 on the base 1. In step (D), the electrically conductive layer 3 on the interconnecting areas 5 is removed by way of micro etching, so that the interconnecting areas 5 on the first wiring layer 2 are pure copper foils. Instep (E), solid cylindrical copper interconnecting bodies 6 are separately formed on the pure copper foils of the interconnecting areas 5 by way of electric plating. The electric plating continues until the cylindrical copper interconnecting bodies 6 reach a desired height. In step (F), the dry-film resist 4 is removed, so that the solid cylindrical copper interconnecting bodies 6 consisting of pure copper project from the interconnecting areas 5. Thereafter, a second wiring layer is provided over the first wiring layer 2 on the PCB by way of a laminating method known in the art, so that the second wiring layer is electrically connected to the first wiring layer 2 via the solid cylinder copper interconnecting bodies 6. The above-described method may also be used to manufacture a multi-layer PCB having more than two wiring layers electrically connected via solid cylindrical copper interconnecting bodies.

What is claimed is:

1. A method of manufacturing a printed circuit board having wiring layers electrically connected via solid cylindrical copper interconnecting bodies, comprising the following steps:
a. Preparing a base or an insulated layer that is locally provided at one side with a layer of copper foil to serve as a first wiring layer;
b. Fully coating said first wiring layer with an electrically conductive layer;
c. Coating areas on said first wiring layer that are not used for interconnection purpose with a layer of dry-film resist to protect these areas against subsequent electric plating process, such that other areas on said first wiring layer that are to be used for interconnection purpose are exposed to outside and form interconnecting areas on said base or said insulating layer;
d. Removing said electrically conductive layer on said interconnecting areas by way of micro etching, so that said interconnecting areas on said first wiring layer are pure copper foils;
e. Forming solid cylindrical copper interconnecting bodies on said pure copper foils of said interconnecting areas by way of electric plating, and continuing said electric plating until said solid cylindrical copper interconnecting bodies reach a desired height;
f. Removing said dry-film resist, so that said solid cylindrical copper interconnecting bodies consisting of pure copper project from said interconnecting areas; and
g. Providing a second wiring layer over said first wiring layer on said printed circuit board, so that said second wiring layer is electrically connected to the first wiring layer via said solid cylinder copper interconnecting bodies.

2. A printed circuit board having wiring layers electrically connected via solid cylindrical copper interconnecting bodies, comprising solid cylindrical copper interconnecting bodies being formed through the method as claimed in claim 1.
